(19) United States
(12) Patent Application Publication
(10) Pub. No.: US 2008/0052575 A1
(43) Pub. Date: Feb. 28, 2008

(54) Digital apparatus and method of testing the same

(75) Inventor: Jae-Young Jang, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/892,225

(22) Filed: Aug. 21, 2007

(30) Foreign Application Priority Data
Aug. 22, 2006 (KR) 10-2006-79451

(51) Int. Cl. G01R 31/28

(52) U.S. Cl. 714/724

(57) ABSTRACT

A digital apparatus and a method of testing the same according to example embodiments which may reduce the amount of data exchanged because the digital apparatus may provide a pass/fail signal to the tester.

### PRIORITY STATEMENT

This application claims priority under 35 USC §119 to Korean Patent Application No. 2006-0079451, filed on Aug. 22, 2006 in the Korean Intellectual Property Office (KIPO), the entire contents of which are incorporated herein by reference.

### BACKGROUND

1. Field

Example embodiments are directed to a method of testing a digital apparatus and a digital apparatus including a test circuit.

2. Description of the Related Art

To increase the operation speed of a digital apparatus, the number of bits of a bus that exchanges data externally may be increased. For example, data exchange through a 128-bit bus may be faster than data exchange through a 64-bit bus. When the number of the bits of the bus increases, performance of the digital apparatus may be enhanced. However, the number of pins to be tested may increase as the number of bits of the bus increases.

For example, when semiconductor apparatuses, including multi-bit buses, are tested by a conventional tester apparatus, pins of the bus may be connected to the tester apparatus through probes for exchanging test command, test data, and result data. Accordingly, the tester apparatus may be required to include a number of probes that may be comparable to the number of pins. Additionally, skew between higher-speed signals that are transmitted through the probes may require compensation and/or noise reduction during transmission.

There have been attempts to reduce the number of the probes that may be required for testing the semiconductor apparatus. For example, there have been attempts to reduce the size of the test command, test data, and the result data that may be simultaneously inputted and/or outputted when the semiconductor apparatus is tested.

When testing a semiconductor memory device, for example, a test pattern may be relatively monotonous, and the size of pattern data may be relatively small and thus the test may be performed by repetitively increasing or decreasing addresses. A built-in self test (BIST) circuit may be included in the semiconductor apparatus if test pattern is relatively monotonous, for example. A semiconductor memory apparatus adopting a BIST may be tested by a BIST circuit having a self-test algorithm. The test may be performed by applying a test command from an external source, and the semiconductor memory apparatus including the BIST circuit may provide a result of the test.

A BIST method may not be economical for given testing situations. When testing a hardware video decoder, for example, a test pattern may not be monotonous but may be complex, and the size of pattern data may be great. Thus, a wider bandwidth may be required for inputting and outputting the test data.

In an example of a conventional method of testing a hardware video decoder, the tester apparatus may determine whether the hardware video decoder passes or fails a test. For example, the tester apparatus may transmit hundreds of mega-bytes of test data per second to the hardware video decoder and simultaneously receive decoded data from the hardware video decoder to determine whether the decoder is operating normally.

In an example of a conventional test method, the tester apparatus may transmit data, a control signal, and a clock signal through the probes to the pins of the semiconductor apparatus under test when test is performed. The semiconductor apparatus under test may perform some operations based on the transmitted data, the control signal, and the clock signal and may provide the test result data to the tester apparatus. The tester apparatus may compare the test result data with reference data that the semiconductor apparatus device under test may provide when the semiconductor apparatus operates normally, and the tester apparatus may determine if the semiconductor apparatus passes or fails the test.

When the decoder of the semiconductor apparatus determines the result of the test, for example, the decoder may require an extra internal space to store the test pattern data, which may be tens or hundreds of mega-bytes in size, and may require a built-in test circuit for processing the test pattern data to determine the result of the test. Including extra space and the built-in test circuit in the semiconductor apparatus may be inefficient.

### SUMMARY

Inefficiencies, like the inefficiency discussed above, may be reduced when, for example, testing a semiconductor device uses a smaller storage space and a simpler test circuit.

Example embodiments provide a method of testing a digital apparatus, capable of outputting a test result signal by performing a test in the digital apparatus.

Additional example embodiments provide a digital apparatus, which may include a test circuit, capable of outputting a test result signal.

According to example embodiments, a digital apparatus may process input data to generate output data. The digital apparatus may make a determination as to whether an operation mode corresponds to a normal mode or a test mode. When the operation mode corresponds to a normal mode, unchanged output data may be provided, for example. Additionally, a pass/fail signal based on a comparison result of a reference conversion value and an output conversion value may be provided when the operation mode corresponds to a test mode. For example, the reference conversion value may be converted from reference data, and the output conversion value may be converted from the output data.

According to example embodiments, the output data may be converted to the output conversion value. The size of the output conversion value may be smaller than a size of the output data.

The output data may be converted to the output conversion value using a Cyclic Redundancy Check (CRC) algorithm, for example.

The pass/fail signal may be generated, and according to example embodiments, the pass/fail signal may have a first pass/fail value when the reference conversion value is identical to the output conversion value. Additionally, the pass/fail signal may have a second pass/fail value when the reference conversion value is different from the output conversion value.

The pass/fail signal may be a one-bit signal. The first pass/fail value may correspond to a first logic level, and the second pass/fail value may correspond to a second logic level, for example. The first logic level may correspond to logic “high”, and the second logic level may correspond to logic “low”.

According to example embodiments, a digital apparatus may include a process unit, a data input/output (I/O) port, a test circuit, and a test output port. The process unit may process input data to generate output data. The data input/output (I/O) port may provide the output data externally when an operation mode is a normal mode. The test circuit may generate a pass/fail signal based on a comparison result of a reference conversion value and an output conversion value when the operation mode is a test mode. In example embodiments, the reference conversion value may be converted from reference data, and the output conversion value may be converted from the output data. The test output port may provide the pass/fail signal externally when the operation mode is the test mode.

The test circuit may include a calculator that converts the output data to the output conversion value such that a size of the output conversion value is smaller than a size of the output data.

The calculator may convert the output data to the output conversion value using a Cyclic Redundancy Check (CRC) algorithm, for example.

The test circuit may include a comparator that generates the pass/fail signal having a first pass/fail value when the reference conversion value is identical to the output conversion value, and having a second pass/fail value when the reference conversion value is different from the output conversion value.

The test circuit may include a first register storing the reference conversion value, and a second register storing the output conversion value.

The test circuit may include a multiplexer that outputs the pass/fail signal or a default signal based on a test out enable signal when the operation mode is the test mode. The test out enable signal may be enabled during a time interval after the comparison of the reference conversion value and the output conversion value is completed. The multiplexer may output the pass/fail signal when the test out enable signal is enabled, and output the default signal when the test out enable signal is disabled, for example.

The process unit may perform a decoding operation. The test output port may be a general purpose I/O port, for example.

According to example embodiments, the method of testing a digital apparatus and a digital apparatus including a test circuit may test the digital apparatus by reducing the data exchanged between the digital apparatus and an external tester.

### BRIEF DESCRIPTION OF THE DRAWINGS

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 is a flow chart illustrating a method of testing a digital apparatus according to example embodiments.

FIG. 2 is a block diagram illustrating a digital apparatus including a test unit according to example embodiments.

FIG. 3 is a timing diagram illustrating an operation sequence of a test circuit according to example embodiments.

### DESCRIPTION OF EXAMPLE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Example embodiments disclose that, when there is a need for comparing larger amounts of data, the larger data may be reversibly or irreversibly converted to smaller amounts of data for a convenient comparison. A lossy or lossless compression algorithm, a check sum algorithm, an encoding algorithm, and an authorization code generation algorithm, or other like algorithms may be adopted for converting the larger data into the smaller data. For example, a Cyclic Redundancy Check (CRC) algorithm may be adopted for the conversion methods.

The CRC algorithm may be used in checking transmitted data for errors. For example, in a system employing the CRC algorithm, a transmitter may calculate a first CRC value using the CRC algorithm based on given data, attach the first CRC value to the given data, and transmit the data including the first CRC value. A receiver may calculate a second CRC value using the CRC algorithm based on received data provided from the transmitter, and compare the first CRC value with the second CRC value. For example, when the first CRC value is different from the second CRC value, the received data may have errors that occurred during transmission due to noise, or other like interferences.

The probability that the first CRC value is different from the second CRC value may be low, for example, because errors may not frequently occur during transmission. Additionally, the probability that the first CRC value is identical with the second CRC value may be low if errors do occur during transmission. The CRC algorithm may be suitable for implementing binary-based hardware, for example.

Example embodiments disclose that an operation testing a digital semiconductor apparatus may be different from an operation detecting whether transmitted data have received errors during transmission. However, the method of testing the digital semiconductor apparatus may compare CRC values to determine whether the digital semiconductor apparatus is operating normally.

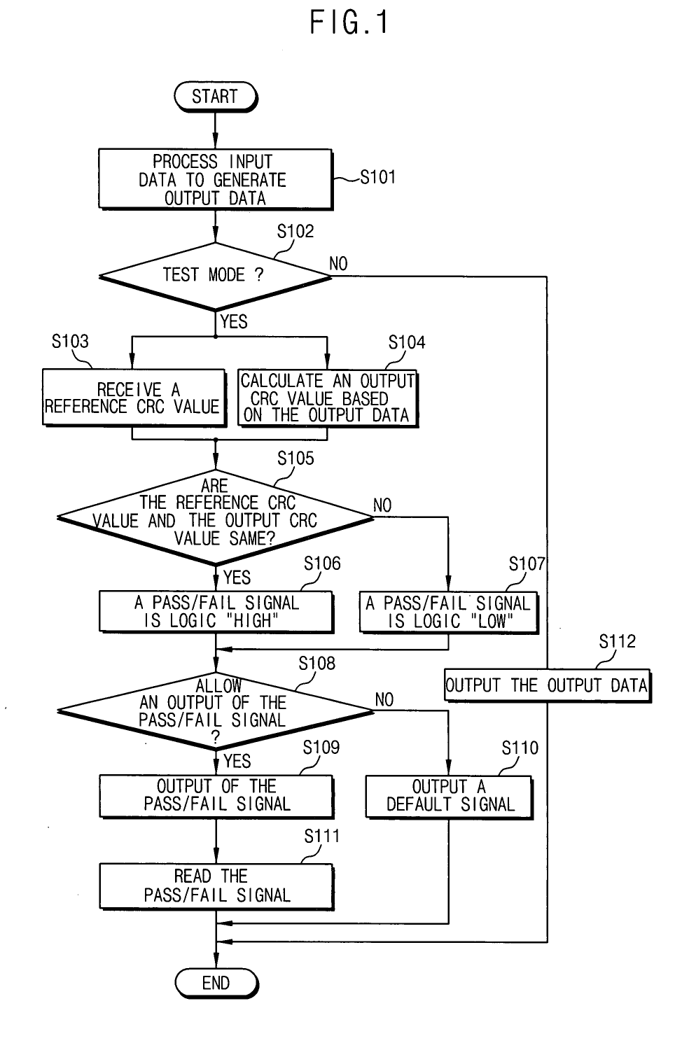

FIG. 1 is a flow chart illustrating a method of testing a digital apparatus according to example embodiments.

Referring to FIG. 1, according to example embodiments of the method of testing the digital apparatus, CRC values may be internally compared in the digital apparatus to determine a pass/fail result of the digital apparatus, and a one-bit test result may be provided.

The digital apparatus may receive input data, process the received input data, and generate output data. The digital apparatus may be expected to generate the same output data for given input data when the digital apparatus operates normally, for example. Accordingly, whether the digital apparatus operates normally may be determined by comparing the output data with reference data that is expected to be outputted for given input data when the digital apparatus operates normally. For example, the output data and the reference data may be converted to a smaller amount of data through a lossy or lossless compression algorithm, such as the check sum algorithm, the encoding algorithm, and the authorization code generation algorithm, the CRC algorithm, or other like algorithm. As a result of this conversion, converted output data of a smaller size than the output data may be compared with converted reference data of a smaller size than the reference data.

Hereinafter, the CRC algorithm shall be discussed as an example of a group including the above-mentioned algorithms and other like algorithms. However, it is obvious that persons skilled in the art may implement example embodiments of the test method using algorithms drawn from this group or other algorithms.

The digital apparatus may receive input data and process the received input data to generate output data (S101). The digital apparatus may operate in a normal mode or a test mode. The digital apparatus may determine whether an operation mode corresponds to the normal mode or the test mode (S102). The digital apparatus may provide the output data unchanged (S112) when the operation mode corresponds to the normal mode (S102: NO). When the operation mode corresponds to the test mode (S102: YES), the test may be performed according to the following example embodiments.

For example, in the test mode the digital apparatus may receive a reference CRC value from external source (S103). The reference CRC value may be stored temporarily. The reference CRC value may correspond to a CRC value of the reference data expected to be output for given input data when the digital apparatus operates normally, and an output CRC value may be calculated based on the output data (S104). The output CRC value may also be stored temporarily.

The output CRC value may be compared with the reference CRC value (S105). A pass/fail signal may be generated (S106 & S107) according to a result of the comparison. When the output data are generated normally, the output CRC value may be identical to the reference CRC value. However, when the output data are not generated normally, the output CRC value may be different from the reference CRC value. Accordingly, the digital apparatus may provide the pass/fail signal with a first logic state such as logic “1” (S106) when the output CRC value is identical to the reference CRC value (S105: YES), for example, when the digital apparatus operates normally. The digital apparatus may provide the pass/fail signal with a second logic state such as logic “0” (S107) when the output CRC value is different from the reference CRC value (S105: NO), for example, when the digital apparatus operates abnormally.

The pass/fail signal may be outputted externally or prevented from being outputted externally according to a state of a test out enable signal. Thus, after the pass/fail signal is completely generated, the pass/fail signal may be outputted externally when the operation mode corresponds to the test mode, for example. When the operation mode corresponds to the normal mode, the pass/fail signal may be prevented from being outputted externally. In other example embodiments, although the operation mode corresponds to the test mode, the pass/fail signal may be prevented from being outputted externally, such as if the pass/fail signal is not completely determined, to prevent an output of a signal that does not correspond to a real test result. For example, the pass/fail signal may be outputted externally when the pass/fail signal is allowed to be outputted externally in response to one logic state of the test out enable signal (S108 & S109). According to other example embodiments, a default signal may be outputted externally in response to the other logic state of the test out enable signal. The default signal may be outputted externally instead of the pass/fail signal when the pass/fail signal is not completely determined (S108 & S110).

The pass/fail signal may be outputted irrespective of the test out enable signal, for example.

According to example embodiments of the test method, the digital apparatus may provide output data that is unchanged by processing the input data in the normal mode. In alternative example embodiments, the digital apparatus may provide the pass/fail signal by comparing the output CRC value with the reference CRC in the test mode. An external tester may determine whether the digital apparatus operates normally based on the pass/fail signal (S111).

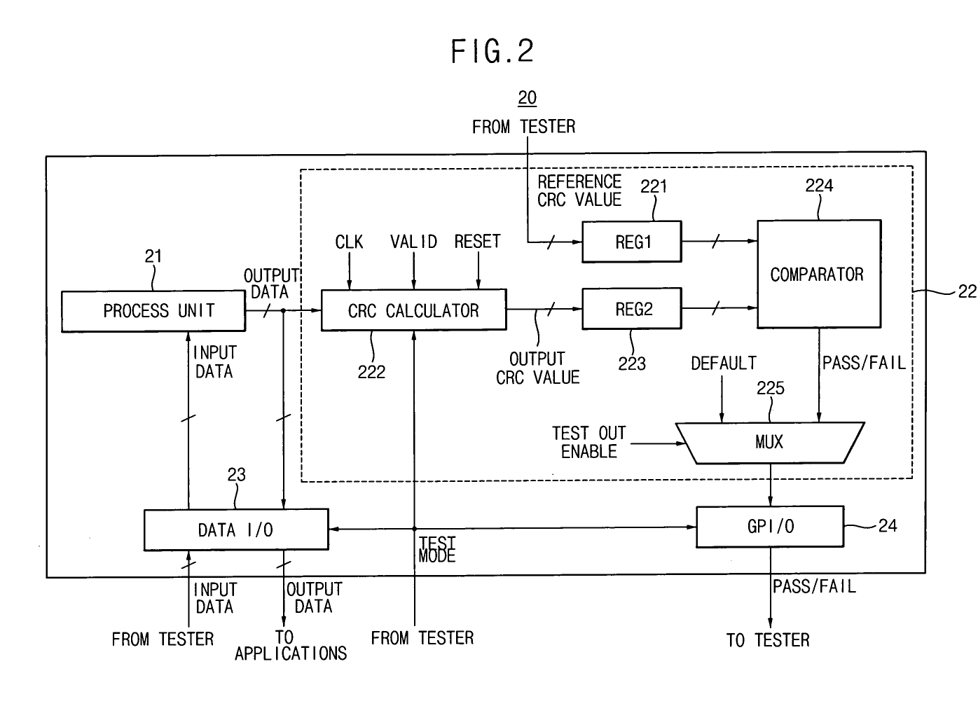

FIG. 2 is a block diagram illustrating example embodiments of a digital apparatus including a test unit.

Referring to FIG. 2, the digital apparatus 20 may include a process unit 21 and a test circuit 22. Output data generated from processing input data may be externally provided through a data input/output (I/O) port 23 in a normal mode, and a pass/fail signal may be provided to a tester (not shown) through a test result output port 24 in a test mode.

The process unit 21 may generate the output data by processing the input data. The input data may be provided from the tester in the test mode.

The test circuit 22 may generate the pass/fail signal in the test mode. The pass/fail signal may be provided to the tester through the test output port 24. The test output port 24 may be a general purpose I/O, for example.

The test circuit 22 may include a first register 221, a CRC calculator 222, a second register 223, a comparator 224, and a multiplexer 225, for example.

The first register 221 may temporarily store a reference CRC value received from the tester. The CRC calculator 222 may calculate an output CRC value based on the output data that is processed by the process unit 21. The CRC calculator 222 may receive a clock signal, a test mode signal, a valid signal, and/or a reset signal to calculate the output CRC value of the output data provided to the CRC calculator 222. The clock signal, the test mode signal, the valid signal, and/or the reset signal may be generated in the digital apparatus 20 or may be provided from the tester. The CRC calculator 222 may be initialized when the reset signal is enabled after the test mode signal is provided, and may calculate the output CRC value based on the output data when the reset signal is disabled and the valid signal is enabled, for example. The valid signal may be disabled when CRC calculator 222 finishes the calculation. The second register 223 may temporarily store the output CRC value.

The comparator 224 may compare the reference CRC value stored in the first register 221 with the output CRC value stored in the second register 223. Example embodiments disclose the comparator 224 may compare the reference CRC value with the output CRC value bit by bit. When the two data are identical to each other, the probability that CRC values of the two data are different from each other may be very low. When the two data are different, the probability that CRC values of the two data are identical to each other may be low. Accordingly, a result of comparing the CRC values may correspond to a result of comparing the original data. As a result of the comparison, the digital apparatus 20 may be determined to be normal and may output the pass/fail signal indicating a normal operation when the reference CRC value and the output CRC value are identical. According to alternative example embodiments, the digital apparatus 20 may be determined to be abnormal and may output the pass/fail signal indicating an abnormal operation when the reference CRC value and the output CRC value are different. The pass/fail signal may be a one-bit signal, for example.

The multiplexer 225 may output either the pass/fail signal or the default signal based on the test out enable signal. The multiplexer 225 may output the pass/fail signal while the test out enable signal is enabled.

The data I/O port 23 and the test result output port 24 may operate alternatively in response to the test mode signal. The data I/O port 23 may provide the output data when digital apparatus 20 operates in the normal mode while the test result output port 24 does not operate. The test result output port 24 may provide the default signal outputted from the multiplexer 225 when the test result output port 24 provides a signal abnormally. The test result output port 24 may provide either the pass/fail signal or the default signal when the digital apparatus 20 operates in the test mode while the data I/O port 23 does not operate.

The tester may provide input data, a clock signal, and various control signals to the digital apparatus 20 in the test mode, and the tester may receive the pass/fail signal from the digital apparatus 20. Example embodiments disclose the digital apparatus may reduce the number of probes required because the digital apparatus provides a one-bit pass/fail signal.

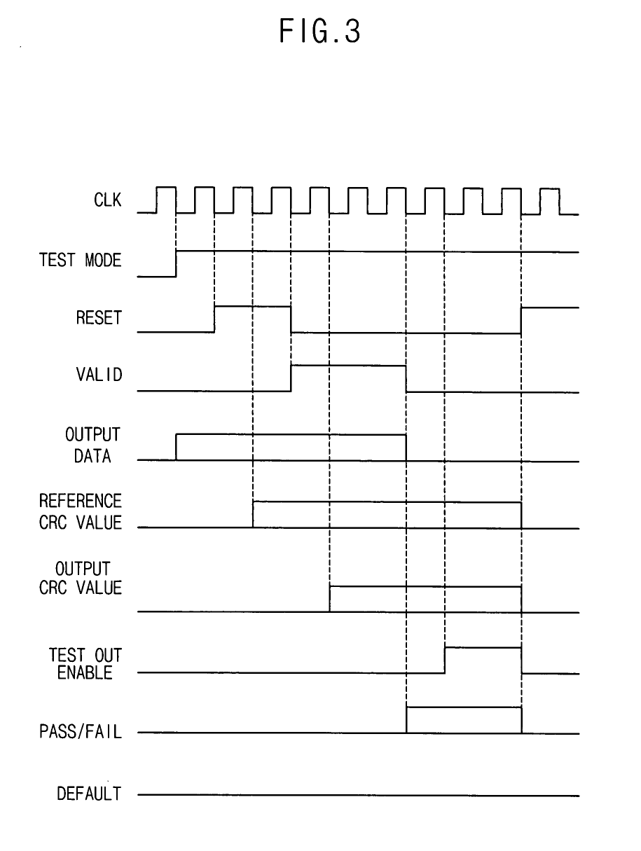

FIG. 3 is a timing diagram illustrating example embodiments of an operation sequence of the test circuit.

Referring to FIG. 3, the test circuit 22 may operate based on the test mode signal, the reset signal, the valid signal, the test out enable signal, or other like signal, for performing sequential processes. Examples of such sequential processes include setting the test mode, inputting the input data, processing the input data, calculating the reference CRC value and the output CRC value, comparing the reference CRC value with the output CRC value, and outputting the pass/fail signal. An operation of the test circuit may be synchronized with the clock signal, for example.

When the test begins, the test mode signal and the reset signal may be enabled, and the test out enable signal may be disabled. The data I/O port 23 may be disabled, and the test output port 24, may be enabled when the enabled test mode signal is enabled. The CRC calculator 225 may be reset according to the reset signal. The MUX 225 may output either the pass/fail signal or the default signal in response to the test out enable signal. The first register 221 may store the reference CRC value received externally. The reset signal may be disabled while the CRC calculator receives the output data, and the CRC calculator may calculate the output CRC value based on the output data when the valid signal is enabled. When the CRC calculation is finished, the second register 223 may store the output CRC value and the valid signal may become disabled. When the CRC calculation is finished, the comparator 224 may compare the reference CRC value with the output CRC value and may generate the pass/fail signal. The multiplexer 225 may provide the pass/fail signal to the test output port 24 when the test out enable signal is enabled, and the test output port 24 may output the pass/fail signal.

The external tester may receive the pass/fail signal to determine whether the digital apparatus 20 is operating normally with respect to given functional items.

The illustrated timing diagram of FIG. 3 only depicts example embodiments, and those skilled in the art may implement various example embodiments by modifying FIG. 3.

Example embodiments disclose a method of testing a digital apparatus and a digital apparatus. Because the digital apparatus may include a test circuit, the digital apparatus may provide a smaller result signal to the external tester and may avoid an external exchange of larger amounts of test pattern data and test result data. Accordingly, because a smaller result signal may be provided to the external tester, the size of a test program that is operated in the external tester may be reduced.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A method of testing a digital apparatus that processes input data to generate output data, the method comprising:
determining whether an operation mode corresponds to a test mode or a normal mode;
providing output data that is unchanged when the operation mode corresponds to the normal mode; and
providing a pass/fail signal based on a comparison result of a reference conversion value and an output conversion value when the operation mode corresponds to the test mode, the reference conversion value being converted from reference data, the output conversion value being converted from the output data.

2. The method of claim 1, wherein providing the pass/fail signal includes converting the output data to the output conversion value such that a size of the output conversion value is smaller than a size of the output data.

3. The method of claim 1, wherein providing the pass/fail signal includes converting the output data to the output conversion value using an algorithm.

4. The method of claim 3, wherein the algorithm is a Cyclic Redundancy Check (CRC) algorithm.

5. The method of claim 2, wherein providing the pass/fail signal includes generating the pass/fail signal that has a first pass/fail value when the reference conversion value is identical to the output conversion value, and that has a second pass/fail value when the reference conversion value is different from the output conversion value.

6. The method of claim 5, wherein the pass/fail signal corresponds to a one-bit signal, the first pass/fail value corresponds to a first logic level, and the second pass/fail value corresponds to a second logic level.

7. The method of claim 6, wherein the first logic level corresponds to a logic “high”, and the second logic level corresponds to a logic “low”.

8. A digital apparatus comprising:
a test circuit configured to generate a pass/fail signal based on a comparison result of a reference conversion value and an output conversion value when the operation mode corresponds to a test mode, wherein
the reference conversion value is converted from reference data, and
the output conversion value is converted from output data generated from input data.

9. The digital apparatus of claim 8, wherein the test circuit includes a calculator that converts the output data to the output conversion value such that a size of the output conversion value is smaller than a size of the output data.

10. The digital apparatus of claim 9, wherein the calculator is configured to convert the output data to the output conversion value using an algorithm.

11. The digital apparatus of claim 10, wherein the algorithm is a Cyclic Redundancy Check (CRC) algorithm.

12. The digital apparatus of claim 8, wherein the test circuit includes a comparator configured to generate the pass/fail signal that has a first pass/fail value when the reference conversion value is identical to the output conversion value, and that has a second pass/fail value when the reference conversion value is different from the output conversion value.

13. The digital apparatus of claim 12, wherein the pass/fail signal corresponds to a one-bit signal, the first pass/fail value corresponds to a first logic level, and the second pass/fail value corresponds to a second logic level.

14. The digital apparatus of claim 13, wherein the first logic level corresponds to a logic “high”, and the second logic level corresponds to a logic “low”.

15. The digital apparatus of claim 8, wherein the test circuit includes a first register storing the reference conversion value, and a second register storing the output conversion value.

16. The digital apparatus of claim 8, wherein the test circuit includes a multiplexer that outputs one of the pass/fail signal and a default signal based on a test out enable signal when the operation mode corresponds to the test mode.

17. The digital apparatus of claim 16, wherein the test out enable signal is enabled during a time interval after the comparison of the reference conversion value and the output conversion value is completed.

18. The digital apparatus of claim 16, wherein the multiplexer outputs the pass/fail signal when the test out enable signal is enabled, and outputs the default signal when the test out enable signal is disabled.

19. A digital apparatus comprising:
a process unit configured to process input data to generate output data;
a data input/output (I/O) port that provides the output data externally when an operation mode corresponds to a normal mode;
a test circuit according to claim 8; and
a test output port that provides the pass/fail signal externally when the operation mode corresponds to the test mode.

20. The digital apparatus of claim 19, wherein the process unit is configured to perform a decoding operation.

21. The digital apparatus of claim 19, wherein the test output port is a general purpose I/O port.
